(19) United States
(12) Patent Application Publication
(10) Pub. No.: US 2009/0146181 A1
(43) Pub. Date: Jun. 11, 2009

(54) INTEGRATED CIRCUIT SYSTEM EMPLOYING DIFFUSED SOURCE/DRAIN EXTENSIONS

(75) Inventors: Chung Woh Lai, Singapore (SG); Oleg Gluschenkov, Poughkeepsie, NY (US); Henry K. Utomo, Newburgh, NY (US); Lee Wee Teo, Singapore (SG); Jin Ping Liu, Singapore (SG); Anita Madan, Danbury, CT (US); Rainer Loesing, Newburgh, NY (US); Jin-Ping Han, Fishkill, NY (US); Hyung-Yoon Choi, Seongnam-si (KR)

Correspondence Address: LAW OFFICES OF MIKIO ISHIMARU, 333 W. EL CAMINO REAL, SUITE 330, SUNNYVALE, CA, 94087, US

(73) Assignees: CHARTERED SEMICONDUCTOR MANUFACTURING LTD., Singapore (SG); INTERNATIONAL BUSINESS MACHINES CORPORATION, Armonk, NY (US); SAMSUNG, Gyeonggi-do (KR); INFINEON TECHNOLOGIES NORTH AMERICA CORPORATION, Milpitas, CA (US)

(21) Appl. No.: 11/952,939

(22) Filed: Dec. 7, 2007

(51) Int. Cl. H01L 29/778; H01L 21/336; H01L 29/78

(52) U.S. Cl. 257/190; 438/285; 257/408; 438/301; 257/E29.266; 257/E21.403; 257/E29.246; 257/E21.409

(57) ABSTRACT

An integrated circuit system that includes: providing a PFET device including a doped epitaxial layer; and forming a source/drain extension by employing an energy source to diffuse a dopant from the doped epitaxial layer.

### TECHNICAL FIELD

The present invention relates generally to integrated circuits, and more particularly to an integrated circuit system employing diffused source/drain extensions.

### BACKGROUND ART

Integrated circuits find application in many of today's consumer electronics, such as cell phones, video cameras, portable music players, printers, computers, etc. Integrated circuits may include a combination of active devices, passive devices and their interconnections.

A common active device within an integrated circuit is the metal-oxide-semiconductor field-effect transistor (MOSFET), which is commonly referred to as a field-effect transistor (FET). A MOSFET generally includes a semiconductor substrate, having a source, a drain, and a channel located between the source and drain. A gate stack including a conductive material (i.e.—a gate) and an oxide layer (i.e.—a gate oxide) are typically located above the channel. During operation, an inversion layer forms a conducting bridge or “channel” between the source and drain when an appropriate voltage is applied to the gate. Both p-channel and n-channel MOSFET technologies are available and can be combined on a single substrate in one technology, called complementary-metal-oxide-semiconductor or CMOS.

As MOSFET technology advances, the semiconductor industry is having to scale to even smaller dimensions to keep pace with Moore's Law. Unfortunately, as the industry scales to smaller critical dimensions, the traditional method of junction formation for source/drain extensions, which uses implantation and rapid thermal anneal, becomes difficult. In order to create a working sub-micron device with good roll-off characteristics, the industry is severely limited by the amount of energy a source/drain extension implant can use and by the temperature used to anneal the device.

Consequently, creating relatively deep and laterally abrupt junctions has become a major challenge for the industry as both diffusion and implantation have the problem of, the deeper the dopant goes within the substrate, the less abrupt the junction becomes (e.g.—due to factors such as transient enhanced diffusion, channeling and implant scattering). Moreover, attempts to solve this problem by creating ultra shallow junctions have been unsuccessful because of the substantial resistive penalty that arises with the use of ultra shallow junctions. However, the aggressive scaling of modern day devices still requires that more dopants be placed deeper within the source/drain extensions, and that these dopants not be too laterally diffused, because dopants that are too laterally diffused will detrimentally overlap with a gates edge causing short channel performance problems.

Thus, a need still remains for a reliable integrated circuit system and method of fabrication, wherein the integrated circuit system possesses highly doped and/or highly abrupt source/drain extensions. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: providing a PFET device including a doped epitaxial layer; and forming a source/drain extension by employing an energy source to diffuse a dopant from the doped epitaxial layer.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross sectional view of an integrated circuit system in an initial stage of manufacture, in accordance with an embodiment of the present invention;

FIG. 2 is the structure of FIG. 1 after formation of an insulation layer;

FIG. 3 is the structure of FIG. 2 after selective etching of an insulation layer;

FIG. 4 is the structure of FIG. 3 after the formation of a recess within a substrate;

FIG. 5 is the structure of FIG. 4 after the selective formation of a doped epitaxial layer over and/or within a PFET source/drain;

FIG. 6 is the structure of FIG. 5 after applying an energy source;

FIG. 7 is the structure of FIG. 6 after further processing;

FIG. 8 is the structure of FIG. 7 after formation of an electrical contact;

FIG. 9 is the structure of FIG. 8 after deposition of a first dielectric layer and a second dielectric layer;

FIG. 10 is a cross sectional view of an integrated circuit system in an initial stage of manufacture, in accordance with another embodiment of the present invention;

FIG. 11 is an exemplary graph depicting the diffusion of boron from a boron-doped epitaxial silicon-germanium junction when using a laser spike anneal process, in accordance with an embodiment of the present invention;

FIG. 12 is an exemplary graph depicting the diffusion of boron from a boron-doped epitaxial silicon-germanium junction when using a rapid thermal anneal process, in accordance with an embodiment of the present invention;

FIG. 13 is an exemplary graph depicting the diffusion of boron from a boron-doped epitaxial silicon-germanium junction when using a rapid thermal anneal process and a laser spike anneal process, in accordance with an embodiment of the present invention;

FIG. 14 is an exemplary graph depicting the diffusion of boron from a boron-doped epitaxial silicon-germanium junction when using a rapid thermal anneal process and a laser spike anneal process, in accordance with an embodiment of the present invention

FIG. 15 is an exemplary graph depicting an Ion-Ioff performance curve for a typical 45 nm bulk baseline device formed without epitaxial silicon-germanium regions (i.e.—ion implantation was used to form the extension junctions) and a 45 nm epitaxially assisted source/drain extension device formed with epitaxial silicon-germanium regions, in accordance with an embodiment of the present invention;

FIG. 16 is a flow chart of an integrated circuit system for an integrated circuit system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGs. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

The terms “example” or “exemplary” are used herein to mean serving as an instance or illustration. Any aspect or embodiment described herein as an “example” or as “exemplary” is not necessarily to be construed as preferred or advantageous over other aspects or designs.

The term “system” as used herein means and refers to the method and to the apparatus of the present invention in accordance with the context in which the term is used.

The term “on” is used herein to mean there is direct contact among elements.

Generally, the present invention enables the development of 45 nanometer and below gate length devices employing intermediate depth laterally diffused heavily doped source/drain extension junctions with an abrupt junction profile. The present inventors achieved this advancement by strategically engineering the design of a gate sidewall spacer to allow formation of an epitaxially doped material offset a specified small distance from a gate. The epitaxially doped material can then be subjected to a high temperature millisecond anneal process, which forms highly doped and/or highly abrupt source/drain extensions by the diffusion of the epitaxially incorporated dopants from the doped epitaxial/substrate interface. Accordingly, it has been discovered by the present inventors that highly doped and/or highly abrupt source/drain extensions can be formed without employing a damaging extension implant.

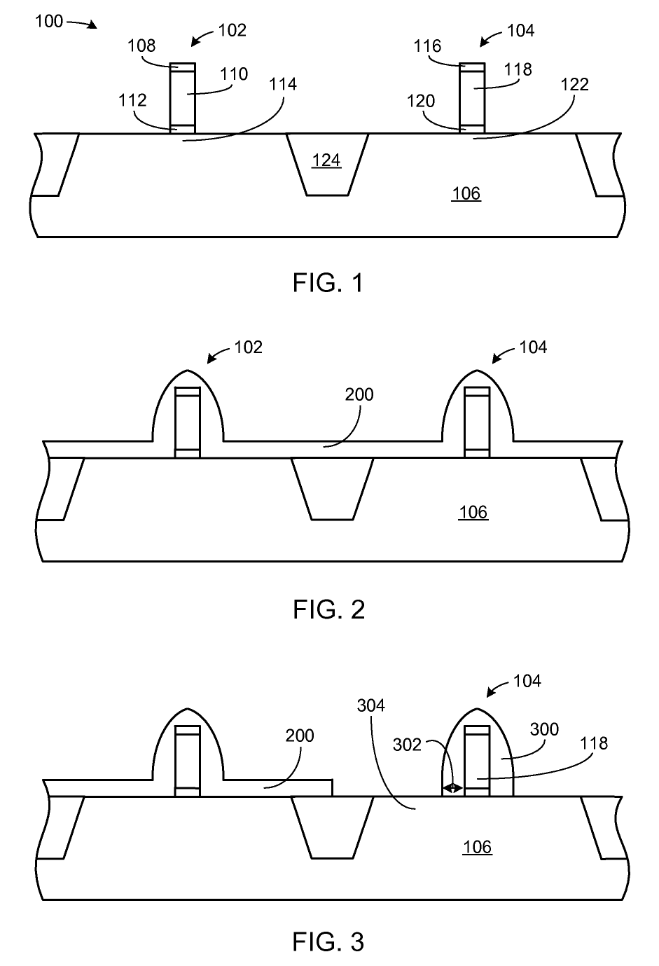

FIGS. 1-10, which follow, depict by way of example and not by limitation, an exemplary process flow for the formation of an integrated circuit system and they are not to be construed as limiting. It is to be understood that a plurality of conventional processes that are well known within the art and not repeated herein, may precede or follow FIGS. 1-10. Accordingly, it is to be understood that many modifications, additions, and/or omissions may be made to the below described process without departing from the scope or spirit of the claimed subject matter. For example, the process may include more, fewer, or other steps.

Additionally, it is to be appreciated that the integrated circuit system of the present disclosure may include any number of multi-electrode devices in which the current flowing between two specified electrodes is controlled or modulated by the voltage applied at a control electrode. Exemplary illustrations may include an n-channel field effect transistor (NFET), a p-channel field effect transistor (PFET), a complementary metal-oxide-silicon (CMOS) configuration, a single-gate transistor, a multi-gate transistor, a fin-FET, or an annular gate transistor. Accordingly, although FIGS. 1-10 depict application of the below described exemplary process flow to a PFET device, it is to be understood that the exemplary process flow may also apply to an NFET device, wherein a diffused NFET source/drain extension is formed by filling a recess adjacent an NFET gate with a Group VA doped epitaxial material and annealing to diffuse the Group VA dopant into the NFET source/drain extension region.

Furthermore, it is to be understood that one or more of the integrated circuit system could be prepared at one time on a medium, which could then be separated into individual or multiple integrated circuit assemblies at a later stage of fabrication.

### Embodiment One

Referring now to FIG. 1, therein is shown a cross sectional view of an integrated circuit system 100 in an initial stage of manufacture, in accordance with an embodiment of the present invention. The integrated circuit system 100 can be formed from conventional deposition, patterning, photolithography, and etching to form an NFET device 102 and a PFET device 104. The NFET device 102 and the PFET device 104 may operate together, thereby forming a complementary metal-oxide-semiconductor (CMOS) configuration.

The NFET device 102 and the PFET device 104 are formed on and/or within a substrate 106. In an aspect of the present invention, the substrate 106 may include any semiconducting material, for example, Si, SiC, SiGe, Si/SiGe, SiGeC, Ge, GaAs, InAs, InP as well as other III/V or II/VI compound semiconductors. Moreover, the substrate 106 may also include silicon-on-insulator configurations.

In a preferred aspect of the embodiment, the substrate 106 is a silicon-containing substrate. The term “silicon-containing substrate” is used herein to denote a semiconductor material that includes at least silicon. Examples of a silicon-containing substrate include, but are not limited to: Si, SiGe, SiC, and/or SiGeC.

In alternative aspects of the embodiment, the substrate 106 may also include doped and undoped configurations, strained configurations, and one or more crystalline orientations (e.g.—<100>, <110>, and/or <111> orientations), which may be strategically employed to optimize carrier mobility within the NFET device 102 and/or the PFET device 104.

However, the examples provided for the substrate 106 are not to be construed as limiting and the composition of the substrate 106 may include any material or configuration that physically and electrically enables the formation of active and/or passive device structures and their interconnections.

The NFET device 102 includes an NFET cap 108, an NFET gate 110, and an NFET gate dielectric 112. The NFET cap 108 is formed over the NFET gate 110 and protects the NFET gate 110 from subsequent processing steps and may include a dielectric material, such as silicon nitride, for example. The NFET gate 110 may be formed from conventional materials including doped and undoped semiconducting materials (such as, for example, polySi, amorphous Si, or SiGe), a metal, a metallic alloy, a silicide, or a combination thereof.

The NFET gate dielectric 112 may be made from materials including, but not limited to, silicon oxide, silicon oxynitride, silicon nitride, a silicon oxide/nitride/oxide stack or a high-k dielectric material (i.e.—one having a dielectric constant value greater than silicon oxide). However, it is to be understood that the type of material chosen for the NFET gate dielectric 112 is not limited to the above examples; for example, the NFET gate dielectric 112 may include any material that permits induction of a charge in a NFET channel 114 when an appropriate voltage is applied to the NFET gate 110.

The PFET device 104 includes a PFET cap 116, a PFET gate 118, and a PFET gate dielectric 120. The PFET cap 116 is formed over the PFET gate 118 and protects the PFET gate 118 from subsequent processing steps and may include a dielectric material, such as silicon nitride, for example. The PFET gate 118 may be formed from conventional materials including doped and undoped semiconducting materials (such as, for example, poly-silicon, amorphous silicon, or SiGe), a metal, a metallic alloy, a silicide, or a combination thereof.

The PFET gate dielectric 120 may be made from materials including, but not limited to, silicon oxide, silicon oxynitride, silicon nitride, a silicon oxide/nitride/oxide stack or a high-k dielectric material (i.e.—one having a dielectric constant value greater than silicon oxide). However, it is to be understood that the type of material chosen for the PFET gate dielectric 120 is not limited to the above examples; for example, the PFET gate dielectric 120 may include any material that permits induction of a charge in a PFET channel 122 when an appropriate voltage is applied to the PFET gate 118.

The substrate 106 may also include an isolation structure 124, such as a shallow trench isolation structure, which can electrically isolate and/or separate the NFET device 102 and the PFET device 104. For purposes of illustration, the isolation structure 124 may be made from a dielectric material such as silicon dioxide (“SiO₂”).

Referring now to FIG. 2, therein is shown the structure of FIG. 1 after formation of an insulation layer 200. The insulation layer 200 can be deposited over the NFET device 102, the PFET device 104, and the substrate 106 with a thickness of about fifty (50) angstroms to about two hundred (200) angstroms. However, it is to be understood that the thickness of the insulation layer 200 is not to be limited by the above exemplary range. In accordance with the scope of the present invention, the insulation layer 200 may include any thickness and is only to be limited by the desired width of a subsequently formed gate sidewall spacer.

Notably, the present inventors have discovered that by strategically controlling and modulating the thickness of the insulation layer 200 that subsequently formed diffused source/drain extensions with sufficient gate edge overlap, a high dopant concentration, and/or an abrupt junction profile can be formed.

By way of example, the insulation layer 200 may include dielectric materials such as a silicon dioxide or silicon nitride. However, it is to be understood that the present invention is not to be limited to this particular example. In accordance with the invention, the insulation layer 200 may include any material that helps to block the deposition of a subsequent layer, such as a silicon germanium layer, for example.

Referring now to FIG. 3, therein is shown the structure of FIG. 2 after selective etching of the insulation layer 200. The etch process forms a PFET gate sidewall spacer 300 by removing selected portions of the insulation layer 200 formed adjacent the PFET device 104. After etching, the PFET gate sidewall spacer 300 should have a width dimension 302 (e.g.—a thickness) of about twenty (20) angstroms to about one hundred fifty (150) angstroms at its interface with the substrate 106. Per this embodiment, the width dimension 302 is defined as the thickness of the PFET gate sidewall spacer 300 at its interface with the substrate 106.

It is to be understood that the width dimension 302 of the PFET gate sidewall spacer 300 can help to determine an offset (e.g.—a distance substantially equivalent to the width dimension 302) of a PFET source/drain 304 from the PFET gate 118. By selectively removing portions of the insulation layer 200 (i.e.—by etching the insulation layer 200 to form the PFET gate sidewall spacer 300) the PFET source/drain 304 has been defined and exposed for further processing. The exposed portions of the PFET source/drain 304 may optionally undergo a cleaning step to remove surface contaminants, such as particles, organics and native oxides.

It is to be understood that the width dimension 302 of the PFET gate sidewall spacer 300 at the interface with the substrate 106 is inversely correlated with the size of the PFET source/drain 304 exposed. For example, as the width dimension 302 of the PFET gate sidewall spacer 300 decreases, the size of the PFET source/drain 304 increases.

By way of example, the etch process used to selectively etch the insulation layer 200 may include a dry etch process, such as reactive ion etching. However, it is to be understood that the etch process of the present embodiment is not to be limited to reactive ion etching and the etch method may include any etch process that selectively removes portions of the insulation layer 200.

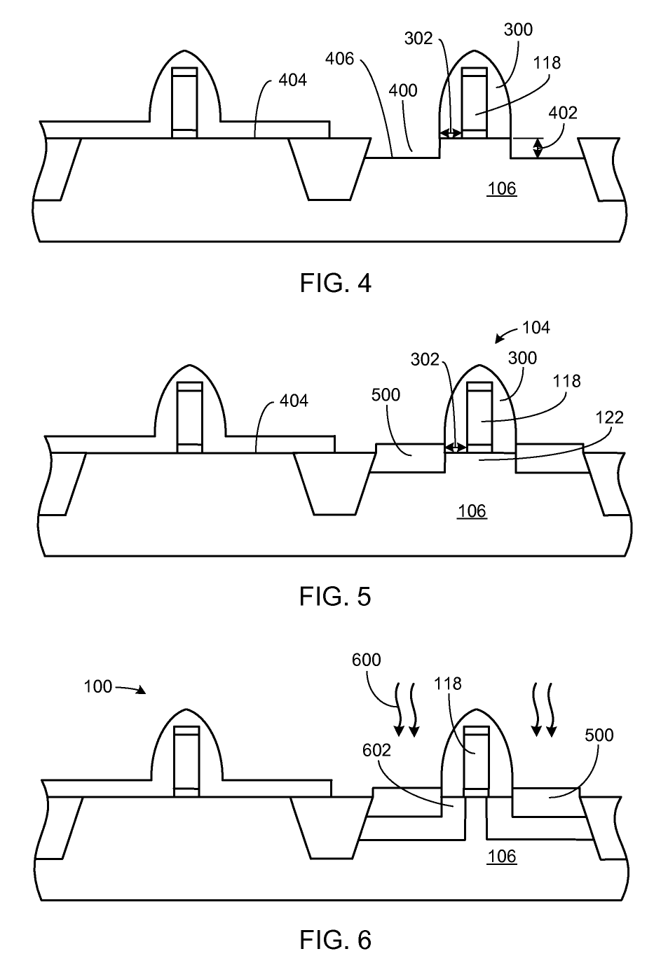

Referring now to FIG. 4, therein is shown the structure of FIG. 3 after the formation of a recess 400 within the substrate 106. During this process step, the recess 400 is formed by an etch process that is highly selective to the material chosen for the substrate 106, for example. Notably, the formation of the recess 400 can be aligned to the PFET gate sidewall spacer 300, thereby helping to locate a subsequently deposited doped epitaxial material in close proximity to the PFET gate 118. However, it is to be understood that an edge of the recess 400 can be aligned with an edge of the PFET gate 118 by employing a slight lateral recess etch within the substrate 106, such that the recess 400 undercuts the PFET gate sidewall spacer 300. Such a technique will help to locate a subsequently deposited doped epitaxial material adjacent and/or in contact with an edge of the PFET gate 118, thereby helping to form a subsequent diffused source/drain extension with sufficient gate edge overlap, a high dopant concentration, and/or an abrupt junction profile.

Generally, a depth dimension 402 of the recess 400 should exceed the width dimension 302 of the PFET gate sidewall spacer 300. Per this embodiment, the depth dimension 402 is defined as the distance between a substrate top surface 404 and a recess bottom surface 406. By way of example, the depth dimension 402 can be about 10 to about 30 nanometers, or alternatively, the depth dimension 402 can be at least two times (2×) the width dimension 302 of the PFET gate sidewall spacer 300. It should be noted that the optimum depth for the depth dimension 402 can be affected by the composition of the substrate 106. For example, a silicon substrate will typically require that the recess 400 be formed deeper than the recess 400 for a silicon-germanium substrate. However, it is to be understood that the above examples are not to be construed as limiting and the depth dimension 402 of the recess 400 may include any depth that helps to lower resistance and/or permits formation of highly doped and/or highly abrupt diffused source/drain extensions.

After etching, the exposed portions of the recess 400 may optionally undergo a cleaning step to remove surface contaminants, such as particles, organics and native oxides.

Referring now to FIG. 5, therein is shown the structure of FIG. 4 after the selective formation of a doped epitaxial layer 500 over and/or within the PFET source/drain 304, of FIG. 3. Notably, the proximity of the doped epitaxial layer 500 to the PFET gate 118 and its effect on a subsequently formed diffused source/drain extensions can be controlled/determined by the width dimension 302 of the PFET gate sidewall spacer 300. It is to be understood that the offset of the PFET source/drain 304, the recess 400 (of FIG. 4), and the doped epitaxial layer 500 from the PFET gate 118 can be modified or adjusted to effectuate a particular result by altering the width dimension 302 of the PFET gate sidewall spacer 300 and/or the optional lateral recess etch process techniques applied to the recess 400 within the substrate 106.

By way of example, the offset of the doped epitaxial layer 500 from the PFET gate 118 can be modified or adjusted to impact upon the subsequent formation of diffused source/drain extensions. The offset of the doped epitaxial layer 500 may impact upon the subsequent formation of diffused source/drain extensions by permitting the formation of diffused source/drain extensions with sufficient gate edge overlap, high dopant concentration, and/or abrupt junction profiles, for example. Accordingly, the present inventors have discovered that by strategically controlling the offset of the doped epitaxial layer 500, for example, by modulating the width dimension 302 of the PFET gate sidewall spacer 300 and/or by employing a lateral recess etch of the substrate 106, that subsequently formed diffused source/drain extensions with enhanced electrical properties for improving short-channel performance of a device can be formed.

Generally, the doped epitaxial layer 500 can be made from any type of semiconductor material that allows diffusion of a dopant to form diffused source/drain extensions between the doped epitaxial layer 500 and the edge of the PFET gate 118. More specifically, and by way of example, the doped epitaxial layer 500 can be made from a p-type doped silicon (Si) or a p-type doped silicon germanium (SiGe), wherein the p-type dopant is selected from Group IIIA of the Periodic Table of Elements. In a preferred aspect of the embodiment, the doped epitaxial layer 500 employs a boron (B) doped silicon-germanium layer or a boron doped silicon layer with a concentration of boron between about 1×10²⁰ (atoms/cm³) to about 3×10²¹ (atoms/cm³). As an exemplary illustration, the doped epitaxial layer 500 can be grown via an in-situ boron doped selective epitaxial growth method that forms raised regions above the substrate top surface 404.

However it is to be understood that the doped epitaxial layer 500 is not to be limited to any particular type of material, dopant, or dopant concentration. In accordance with the present embodiment, the doped epitaxial layer 500 may include any material, dopant, or dopant concentration that is strategically engineered and designed to permit diffusion of the dopant from the doped epitaxial layer 500 to form diffused source/drain extensions between the doped epitaxial layer 500 and the edge of the PFET gate 118.

Additionally, it is to be understood that the thickness of the doped epitaxial layer 500 deposited may include any thickness that permits diffusion of the dopant from the doped epitaxial layer 500 to form diffused source/drain extensions between the doped epitaxial layer 500 and the edge of the PFET gate 118.

Notably, the doped epitaxial layer 500 may also introduce strain within the PFET channel 122, thereby improving the performance of the PFET device 104. It will be appreciated by those skilled in the art that an appropriately applied strain to the channel region of a transistor device may enhance the amount of current that can flow through the device.

Referring now to FIG. 6, therein is shown the structure of FIG. 5 after applying an energy source 600. The energy source 600 is applied to the doped epitaxial layer 500 to form a source/drain extension 602, such as a diffused source/drain extension, between the doped epitaxial layer 500 and the edge of the PFET gate 118. The energy source 600 causes the dopants within the doped epitaxial layer 500 to diffuse laterally towards the PFET gate 118 from the interface of the doped epitaxial layer 500 and the substrate 106.

The present inventors have discovered that by employing a very short duration high energy/temperature anneal (e.g.—the energy source 600 includes a millisecond anneal) that an enhanced diffusion rate can be had for the dopant when diffusing from the doped epitaxial layer 500 (e.g.—a highly doped epitaxial junction). Notably, this enhanced diffusion technique allows the source/drain extension 602 to be formed with sufficient gate edge overlap, a high dopant concentration, and/or a highly abrupt junction profile, thereby improving the performance of the integrated circuit system 100.

The present inventors have also discovered that the energy source 600 may include a very low temperature rapid thermal anneal process followed by a high temperature millisecond anneal process. As an exemplary illustration, the rapid thermal anneal process may include a spike anneal with temperatures ranging from 800° C. to 1020° C. and the millisecond anneal process may include a laser spike anneal with temperatures ranging from 1150° C. to 1400° C. As is known in the art, the millisecond anneal can be of an ultra short duration, ranging from fifty (50) microseconds to five (5) milliseconds. Notably, this enhanced diffusion technique allows the source/drain extension 602 to be formed with sufficient gate edge overlap, a high dopant concentration, and/or a highly abrupt junction profile, thereby improving the performance of the integrated circuit system 100.

Notably, by employing the method or system of the present invention, the source/drain extension 602 exhibits a significantly reduced sheet resistance and the integrated circuit system 100 exhibits markedly improved short channel behavior, such as improved drive current, threshold voltage roll-off, and drain-induced barrier lowering. Moreover, after employing the method or system of the present invention, the integrated circuit system 100 exhibits improved series sheet resistance for the entire device, as well.

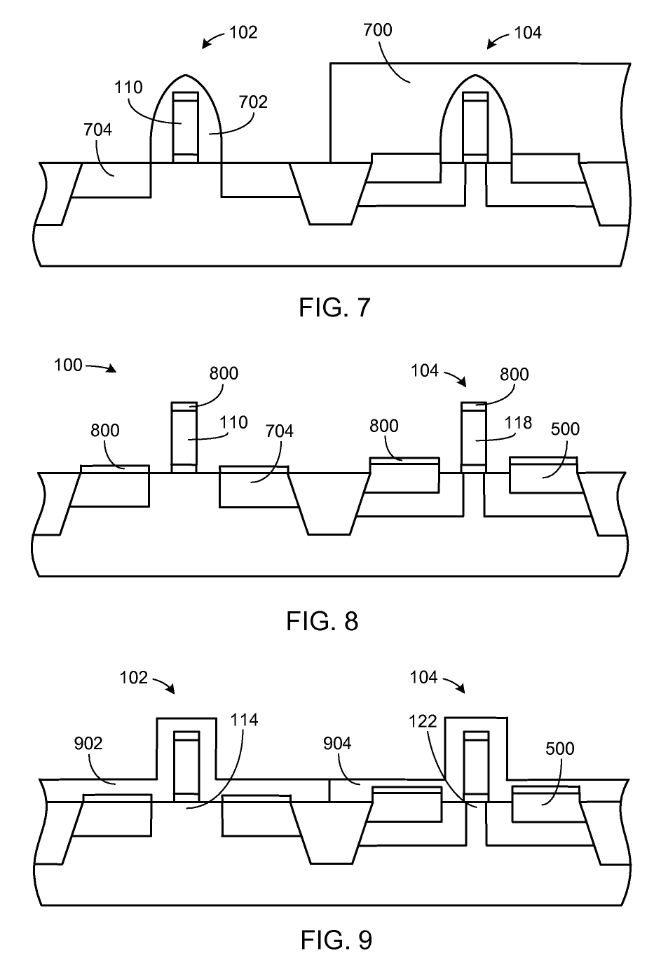

Referring now to FIG. 7, therein is shown the structure of FIG. 6 after further processing. A mask layer 700, such as silicon oxide or silicon nitride, is formed over the PFET device 104 and the insulation layer 200, of FIG. 6, that remains over the NFET device 102 is selectively removed by an etch process that forms an NFET gate sidewall spacer 702. By way of example, the etch process may include a dry etch process, such as reactive ion etching. However, it is to be understood that the etch process of the present embodiment is not to be limited to reactive ion etching and the etch method may include any etch process that selectively removes portions of the insulation layer 200.

After forming the NFET gate sidewall spacer 702, a medium to high dose implant may be performed to form an NFET source/drain 704. Notably, the NFET source/drain 704 can be aligned to the NFET gate sidewall spacer 702, thereby accurately controlling the proximity of the NFET source/drain 704 to the NFET gate 110.

It is to be understood that the mask layer 700 protects the PFET device 104 from the NFET source/drain 704 implant and the etch process that forms the NFET gate sidewall spacer 702.

Referring now to FIG. 8, therein is shown the structure of FIG. 7 after formation of an electrical contact 800. Before forming the electrical contact 800, the mask layer 700, of FIG. 7, is removed from over the PFET device 104, the NFET cap 108, of FIG. 1, can optionally be removed from over the NFET gate 110, and the PFET cap 116, of FIG. 1, can optionally be removed from over the PFET gate 118. By removing the mask layer 700, the NFET cap 108 and the PFET cap 116, the doped epitaxial layer 500, the NFET gate 110 and the PFET gate 118 can be exposed for further processing.

To improve contact formation with the electrically conductive areas of the integrated circuit system 100, a silicide or salicide process may optionally be employed to form the electrical contact 800. By way of example, the electrical contact 800 can be formed over the NFET source/drain 704, the NFET gate 110, the doped epitaxial layer 500, and the PFET gate 118. It is to be understood that the electrical contact 800 may include any conducting compound that forms an interface between the NFET source/drain 704, the NFET gate 110, the doped epitaxial layer 500, and the PFET gate 118 that is thermally stable and provides uniform electrical properties with low resistance. For purposes of illustration, the electrical contact 800 may include materials such as, refractory metals (e.g.—cobalt, platinum, titanium, tungsten, tantalum, and molybdenum).

It is to be understood that the electrical contact 800 can be formed before or after the removal of the NFET gate sidewall spacer 702, of FIG. 7, and the PFET gate sidewall spacer 300, of FIG. 7.

Referring now to FIG. 9, therein is shown the structure of FIG. 8 after deposition of a first dielectric layer 902 and a second dielectric layer 904. The first dielectric layer 902 is deposited over the NFET device 102 and may be engineered to promote a tensile strain within the NFET channel 114. By way of example, the first dielectric layer 902 may include a silicon nitride layer deposited by a plasma enhanced chemical vapor deposition process. The tensile strain within the first dielectric layer 902 can be modulated by deposition parameters, such as, reactant flow rates, pressure, RF power, etc.

The second dielectric layer 904 is deposited over the PFET device 104 and may be engineered to promote a compressive strain within the PFET channel 122. By way of example, the second dielectric layer 904 may include a silicon nitride layer deposited by a plasma enhanced chemical vapor deposition process. The compressive strain within the second dielectric layer 904 can be modulated by deposition parameters, such as, reactant flow rates, pressure, RF power, etc. Notably, the second dielectric layer 904 can augment and/or enhance the compressive strain effects of the doped epitaxial layer 500 upon the PFET channel 122.

### Embodiment Two

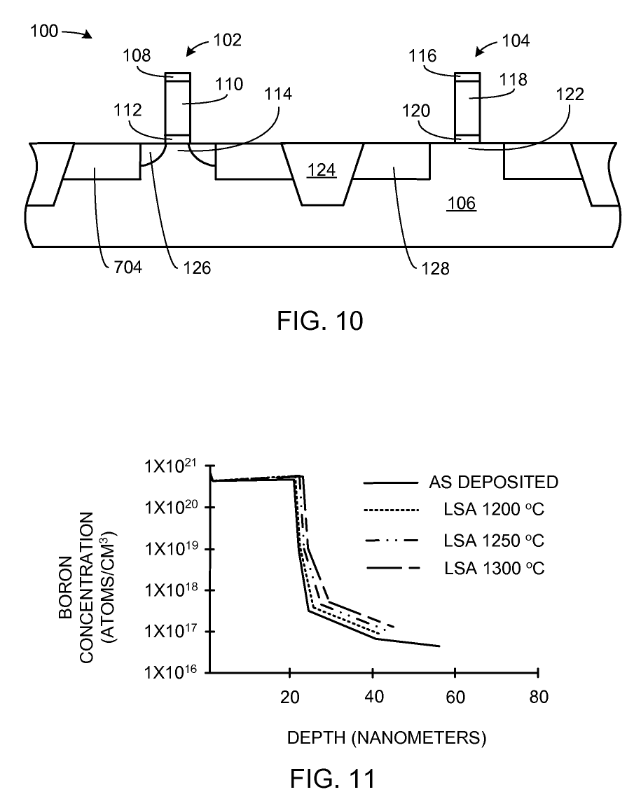

The following alternative embodiment, FIG. 10, depicts by way of example and not by limitation, an optional configuration for the integrated circuit system 100 that can be substituted for the integrated circuit system 100 of FIG. 1. As will be evident to one having ordinary skill in the art, the integrated circuit system 100 of FIG. 10 can proceed through the process steps of FIGS. 2-9, except for the process step of FIG. 7 as the NFET source/drain 704 has already been formed.

Referring now to FIG. 10, therein is shown a cross sectional view of the integrated circuit system 100 in an initial stage of manufacture, in accordance with another embodiment of the present invention. The integrated circuit system 100 can be formed from conventional deposition, patterning, photolithography, and etching to form the NFET device 102 and the PFET device 104. The NFET device 102 and the PFET device 104 may operate together, thereby forming a complementary metal-oxide-semiconductor (CMOS) configuration.

The NFET device 102 and the PFET device 104 are formed on and/or within the substrate 106. In an aspect of the present invention, the substrate 106 may include any semiconducting material, for example, Si, SiC, SiGe, Si/SiGe, SiGeC, Ge, GaAs, InAs, InP as well as other III/V or II/VI compound semiconductors. Moreover, the substrate 106 may also include silicon-on-insulator configurations.

In a preferred aspect of the embodiment, the substrate 106 is a silicon-containing substrate. The term “silicon-containing substrate” is used herein to denote a semiconductor material that includes at least silicon. Examples of a silicon-containing substrate include, but are not limited to: Si, SiGe, SiC, and/or SiGeC.

In alternative aspects of the embodiment, the substrate 106 may also include doped and undoped configurations, strained configurations, and one or more crystalline orientations (e.g.—<100>, <110>, and/or <111> orientations), which may be strategically employed to optimize carrier mobility within the NFET device 102 and/or the PFET device 104.

However, the examples provided for the substrate 106 are not to be construed as limiting and the composition of the substrate 106 may include any material or configuration that physically and electrically enables the formation of active and/or passive device structures and their interconnections.

The NFET device 102 includes the NFET cap 108, the NFET gate 110, the NFET gate dielectric 112, the NFET source/drain 704, and an NFET source/drain extension 126. The NFET cap 108 is formed over the NFET gate 110 and protects the NFET gate 110 from subsequent processing steps and may include a dielectric material, such as silicon nitride, for example. The NFET gate 110 may be formed from conventional materials including doped and undoped semiconducting materials (such as, for example, polySi, amorphous Si, or SiGe), a metal, a metallic alloy, a silicide, or a combination thereof.

The NFET gate dielectric 112 may be made from materials including, but not limited to, silicon oxide, silicon oxynitride, silicon nitride, a silicon oxide/nitride/oxide stack or a high-k dielectric material (i.e.—one having a dielectric constant value greater than silicon oxide). However, it is to be understood that the type of material chosen for the NFET gate dielectric 112 is not limited to the above examples; for example, the NFET gate dielectric 112 may include any material that permits induction of a charge in the NFET channel 114 when an appropriate voltage is applied to the NFET gate 110.

The PFET device 104 includes the PFET cap 116, the PFET gate 118, the PFET gate dielectric 120, and a PFET deep source/drain 128. The PFET cap 116 is formed over the PFET gate 118 and protects the PFET gate 118 from subsequent processing steps and may include a dielectric material, such as silicon nitride, for example. The PFET gate 118 may be formed from conventional materials including doped and undoped semiconducting materials (such as, for example, poly-silicon, amorphous silicon, or SiGe), a metal, a metallic alloy, a silicide, or a combination thereof.

The PFET gate dielectric 120 may be made from materials including, but not limited to, silicon oxide, silicon oxynitride, silicon nitride, a silicon oxide/nitride/oxide stack or a high-k dielectric material (i.e.—one having a dielectric constant value greater than silicon oxide). However, it is to be understood that the type of material chosen for the PFET gate dielectric 120 is not limited to the above examples; for example, the PFET gate dielectric 120 may include any material that permits induction of a charge in the PFET channel 122 when an appropriate voltage is applied to the PFET gate 118.

It is to be understood that a rapid thermal anneal process can be used to overlap the NFET source/drain extension 126 with an edge of the NFET gate 110 and to electrically activate the dopants within each of the NFET source/drain 704 and the PFET deep source/drain 128.

The substrate 106 may also include the isolation structure 124, such as a shallow trench isolation structure, which can electrically isolate and/or separate the NFET device 102 and the PFET device 104. For purposes of illustration, the isolation structure 124 may be made from a dielectric material such as silicon dioxide (“SiO₂”).

Referring now to FIG. 11, therein is shown an exemplary graph depicting the diffusion of boron from a boron-doped epitaxial silicon-germanium junction when using a laser spike anneal process, in accordance with an embodiment of the present invention. The graph depicts the difference in diffusion of boron between an “as-deposited” boron-doped epitaxial silicon-germanium junction and a 1300° C. laser spike annealed boron-doped epitaxial silicon-germanium junction. Notably at a boron concentration of about 1×10¹⁹ (atoms/cm³), there is a difference in diffusion of about five (5) nanometers between the “as-deposited” boron-doped epitaxial silicon-germanium junction and the 1300° C. laser spike annealed boron-doped epitaxial silicon-germanium junction. Typically, for an implanted p-extension junction, the difference in diffusion is about one (1) nanometer for an “as-deposited” boron-doped p-extension as compared to a 1350° C. laser spike annealed boron-doped p-extension at a boron concentration of about 1×10¹⁹ (atoms/cm³).

Accordingly, this graph depicts how a boron-doped epitaxial silicon-germanium junction (i.e.—a junction formed without implantation) can be annealed to form a diffused source/drain extension with sufficient gate edge overlap, a high dopant concentration, and/or a highly abrupt junction profile.

Notably, the abruptness (nm/dec) of boron from an “as-deposited” boron-doped epitaxial silicon-germanium junction as compared to a 1300° C. laser spike annealed boron-doped epitaxial silicon-germanium junction, varies between about 1.5 to about 3.5, respectively. Accordingly, it is to be understood that the present invention enables an order of magnitude of change in the atomic concentration of boron in 3.5 nanometers or less.

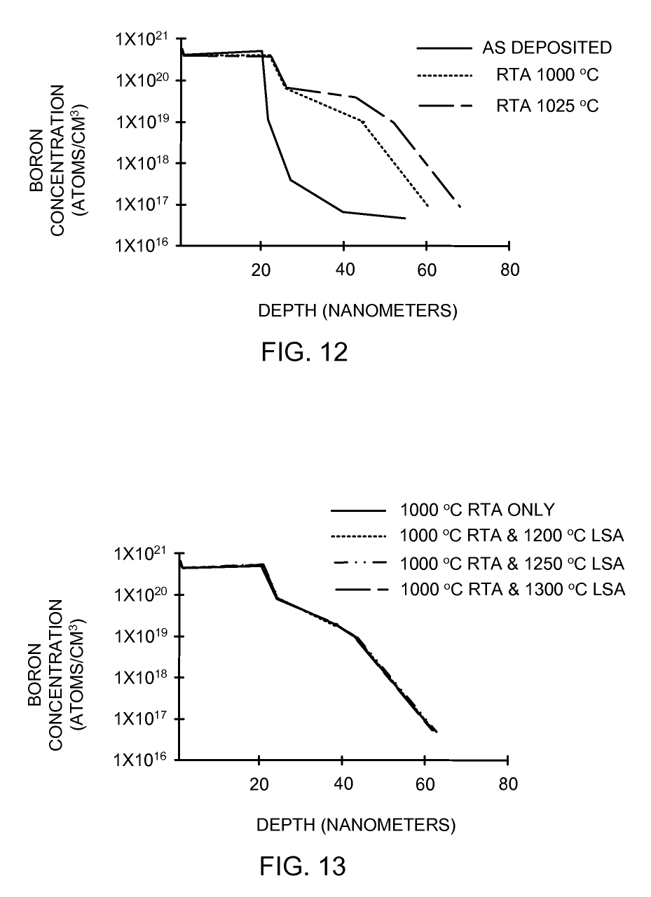

Referring now to FIG. 12, therein is shown an exemplary graph depicting the diffusion of boron from a boron-doped epitaxial silicon-germanium junction when using a rapid thermal anneal process, in accordance with an embodiment of the present invention. The graph depicts the difference in diffusion of boron between an “as-deposited” boron-doped epitaxial silicon-germanium junction, a 1000° C. rapid thermal annealed (e.g.—a spike anneal) boron-doped epitaxial silicon-germanium junction, and a 1025° C. rapid thermal annealed (e.g.—a spike anneal) boron-doped epitaxial silicon-germanium junction. Notably at a boron concentration of 1×10¹⁹ (atoms/cm³), there is a difference in diffusion of about thirty (30) nanometers between the “as-deposited” boron-doped epitaxial silicon-germanium junction and the 1025° C. rapid thermal annealed boron-doped epitaxial silicon-germanium junction.

It can be seen from the graph that the diffusion rate of boron, at a concentration of about 1×10¹⁹ atoms/cm³, from a boron-doped epitaxial silicon-germanium junction (e.g.—from the interface of the doped epitaxial layer 500, of FIG. 5, and the substrate 106, of FIG. 5) can be calculated as about 0.28 nm/° C. from the following equation:

(52−45)nm/(1025−1000)° C.=7/25 nm/° C.=0.28 nm/° C.

Typically, the rate of diffusion for a boron implanted p-extension junction at a concentration of about 1×10¹⁹ atoms/cm³ is about 0.106 nm/° C. when rapid thermal annealing samples between 1025° C. and 1091° C. Accordingly, the present inventors have discovered an enhanced diffusion technique that enables a greater diffusivity rate for boron at a lower temperature by employing a boron-doped epitaxial silicon-germanium junction (i.e.—the doped epitaxial layer 500, of FIG. 5).

Notably, the abruptness (nm/dec) of boron from an “as-deposited” boron-doped epitaxial silicon-germanium junction as compared to a 1025° C. rapid thermal annealed boron-doped epitaxial silicon-germanium junction, varies between about 1.5 to about 7, respectively. Accordingly, it is to be understood that the present invention enables an order of magnitude of change in the atomic concentration of boron in seven (7) nanometers or less.

Additionally, it should be noted that the resistivity (ohm/sq) of an “as-deposited” boron-doped epitaxial silicon-germanium junction as compared to a 1025° C. rapid thermal annealed boron-doped epitaxial silicon-germanium junction, varies between about 230 to about 153, respectively.

Referring now to FIG. 13, therein is shown an exemplary graph depicting the diffusion of boron from a boron-doped epitaxial silicon-germanium junction when using a rapid thermal anneal process and a laser spike anneal process, in accordance with an embodiment of the present invention. The graph depicts the difference in diffusion of boron from a boron-doped epitaxial silicon-germanium junction for a 1000° C. rapid thermal anneal only sample, a 1000° C. rapid thermal anneal and a 1200° C. laser spike anneal sample, a 1000° C. rapid thermal anneal and a 1250° C. laser spike anneal sample, and a 1000° C. rapid thermal anneal and a 1300° C. laser spike anneal sample. Notably at a boron concentration of 1×10¹⁹ (atoms/cm³), there is a minimal difference in diffusion (e.g.—about four (4) nanometers) between the 1000° C. rapid thermal anneal only sample and the 1000° C. rapid thermal anneal with a 1200° C., 1250° C., or 1300° C. laser spike anneal samples. Accordingly, this graph depicts how a boron-doped epitaxial silicon-germanium junction (i.e.—a junction formed without implantation) can be annealed to form a diffused source/drain extension with sufficient gate edge overlap, a high dopant concentration, and/or a highly abrupt junction profile.

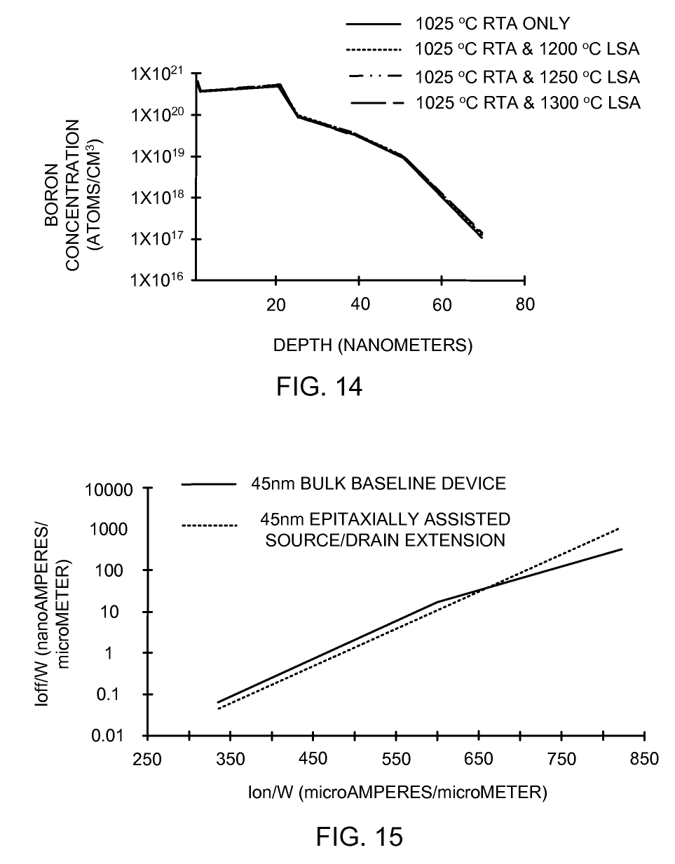

Referring now to FIG. 14, therein is shown an exemplary graph depicting the diffusion of boron from a boron-doped epitaxial silicon-germanium junction when using a rapid thermal anneal process and a laser spike anneal process, in accordance with an embodiment of the present invention. The graph depicts the difference in diffusion of boron from a boron-doped epitaxial silicon-germanium junction for a 1025° C. rapid thermal anneal only sample, a 1025° C. rapid thermal anneal with a 1200° C. laser spike anneal sample, a 1025° C. rapid thermal anneal with a 1250° C. laser spike anneal sample, and a 1025° C. rapid thermal anneal with a 1300° C. laser spike anneal sample. Notably at a boron concentration of 1×10¹⁹ (atoms/cm³), there is a minimal difference in diffusion (e.g.—about four (4) nanometers) between the 1025° C. rapid thermal anneal only sample and the 1025° C. rapid thermal anneal with a 1200° C., 1250° C., or 1300° C. laser spike anneal samples. Accordingly, this graph depicts how a boron-doped epitaxial silicon-germanium junction (i.e.—a junction formed without implantation) can be annealed to form a diffused source/drain extension with sufficient gate edge overlap, a high dopant concentration, and/or a highly abrupt junction profile.

Referring now to FIG. 15, therein is shown an exemplary graph depicting an Ion-Ioff performance curve for a typical 45 nm bulk baseline device formed without epitaxial silicon-germanium regions (i.e.—ion implantation was used to form the extension junctions) and a 45 nm epitaxially assisted source/drain extension device formed with epitaxial silicon-germanium regions, in accordance with an embodiment of the present invention. Per this embodiment, the 45 nm epitaxially assisted source/drain extension device (e.g.—the PFET device 104, of FIG. 7) is formed by the method of the present invention and includes a 1025° C. rapid thermal anneal process with a 1250° C.±50° C. laser spike anneal. This graph illustrates that the inventive concept of the present invention produces a working device with comparable device performance characteristics to that of a 45 nm bulk baseline device formed without epitaxial silicon-germanium regions.

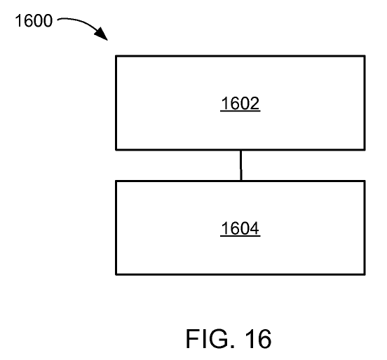

Referring now to FIG. 16, therein is shown a flow chart of an integrated circuit system 1600 for the integrated circuit system 100, in accordance with an embodiment of the present invention. The integrated circuit system 1600 includes providing a PFET device including a doped epitaxial layer in a block 1602; and forming a source/drain extension by employing an energy source to diffuse a dopant from the doped epitaxial layer in a block 1604.

It has been discovered that the present invention thus has numerous aspects. One such aspect is that the present invention enables the formation of highly abrupt and highly activated source/drain extensions without the need for source/drain extension implants. The present invention achieves this by utilizing a high temperature and very short duration anneal process that diffuses dopants from a doped epitaxial layer formed adjacent to the source/drain extensions. The present invention can also achieve the highly abrupt and highly activated source/drain extensions via a very low temperature rapid thermal anneal process followed by a high temperature millisecond anneal process.

Another aspect of the present invention is that it provides enhanced short channel performance by strategically forming the diffused source/drain extension with sufficient gate edge overlap, a high dopant concentration, and/or an abrupt junction profile. Additionally, the doped epitaxial layer can be formed so as to promote a strain within the device channel, thereby further improving device performance.

Another aspect of the present invention is that it reduces the required number of masking steps by eliminating the need for an implanted source/drain extension. Moreover, the present invention also helps to reduce substrate damage by eliminating the need for an ion-implanted source/drain extension.

Another aspect of the present invention is that it is compatible with existing epitaxial silicon-germanium process schemes, and therefore, does not require substantial additional capital outlay and/or re-tooling expenses.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for enhancing PFET device performance. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
providing a PFET device including a doped epitaxial layer; and
forming a source/drain extension by employing an energy source to diffuse a dopant from the doped epitaxial layer.

2. The system as claimed in claim 1 wherein:
providing the PFET device including the doped epitaxial layer includes forming the doped epitaxial layer from silicon germanium.

3. The system as claimed in claim 1 wherein:
providing the PFET device including the doped epitaxial layer includes forming the doped epitaxial layer from silicon.

4. The system as claimed in claim 1 wherein:
forming the source/drain extension by employing the energy source to diffuse a dopant includes diffusing boron.

5. The system as claimed in claim 1 wherein:
forming the source/drain extension by employing the energy source to diffuse a dopant includes a millisecond anneal.

6. An integrated circuit system comprising:
providing a substrate including an NFET device, a PFET device and an isolation structure;
forming an insulation layer over the integrated circuit system;
etching the insulation layer to form a PFET gate sidewall spacer adjacent a PFET gate;
etching the substrate to form a recess;
forming a doped epitaxial layer within the recess; and
annealing the doped epitaxial layer to form a source/drain extension.

7. The system as claimed in claim 6 wherein:
etching the substrate to form the recess includes forming the recess aligned to the PFET gate sidewall spacer.

8. The system as claimed in claim 6 wherein:
forming the doped epitaxial layer within the recess includes forming a boron doped epitaxial silicon-germanium layer or a boron doped epitaxial silicon layer.

9. The system as claimed in claim 6 wherein:
annealing the doped epitaxial layer to form the source/drain extension includes a millisecond anneal or a rapid thermal anneal followed by a millisecond anneal.

10. The system as claimed in claim 6 further comprising:
forming an electrical contact over an NFET source/drain, an NFET gate, the doped epitaxial layer, and the PFET gate.

11. An integrated circuit system comprising:
a PFET device including a doped epitaxial layer; and
a diffused source/drain extension adjacent the doped epitaxial layer.

12. The system as claimed in claim 11 wherein:
the doped epitaxial layer includes silicon-germanium.

13. The system as claimed in claim 11 wherein:
the doped epitaxial layer includes silicon.

14. The system as claimed in claim 11 wherein:
the doped epitaxial layer includes a p-type dopant.

15. The system as claimed in claim 11 wherein:
the doped epitaxial layer includes boron.

16. The system as claimed in claim 11 wherein:
the doped epitaxial layer is offset from a PFET gate by a width dimension of PFET gate sidewall spacer.

17. The system as claimed in claim 11 wherein:
the doped epitaxial layer is within a recess.

18. The system as claimed in claim 11 wherein:
the diffused source/drain extension is between the doped epitaxial layer and a PFET gate.

19. The system as claimed in claim 11 wherein:
the diffused source/drain extension overlaps with a PFET gate edge.

20. The system as claimed in claim 11 wherein:
the PFET device is part of a CMOS configuration.
